(19) United States
(12) Patent Application Publication
(10) Pub. No.: US 2020/0321186 A1
(43) Pub. Date: Oct. 8, 2020

(54) METHOD AND APPARATUS FOR ANGLED ETCHING

(71) Applicant: Applied Materials, Inc., Santa Clara, CA (US)

(72) Inventors: John M. WHITE, Hayward, CA (US); Yang YANG, San Diego, CA (US); Kartik RAMASWAMY, San Jose, CA (US); Manivannan THOTHADRI, Mountain View, CA (US); Yue GUO, Redwood City, CA (US)

(21) Appl. No.: 16/373,254

(22) Filed: Apr. 2, 2019

(51) Int. Cl. H01J 37/063; H01J 37/077; H01J 37/32

(52) U.S. Cl. CPC H01J 37/063; H01J 37/077; H01J 2237/3174; H01J 37/32568; H01J 37/3255

(57) ABSTRACT

Embodiments described herein relate to apparatus and methods for performing electron beam reactive plasma etching. In one embodiment, an apparatus for performing EBRPE processes includes an electrode formed from a material having a high secondary electron emission coefficient. The electrode has an electron emitting surface disposed at a nonparallel angle relative to a major axis of a substrate assembly. The EBRPE apparatus may further comprise a capacitive or inductive coupled plasma generator. In another embodiment, methods for etching a substrate include generating a plasma and bombarding an electrode with ions from the plasma to cause the electrode to emit electrons. The electrons are accelerated toward a substrate to induce directional etching of the substrate. During the EBPRE process, the substrate or electrode is actuated through a process volume during the etching.

### BACKGROUND

### Field

Embodiments of the present disclosure generally relate to methods and apparatus for etching a substrate. More specifically, embodiments described herein relate to methods and apparatus for electron beam reactive plasma etching.

### Description of the Related Art

In the semiconductor and display manufacturing industries, various technological advances have enabled production of increasingly complex devices at advanced technology nodes. For example, device feature sizes have been reduced to the nanometer scale and the geometric complexity of such features has grown increasingly complex. Etching processes used to fabricate such devices are often a limiting factor in further development of advanced devices.

Reactive ion etching (RIE) is a conventional etching technique which utilizes ion bombardment to induce etching reactions on a substrate. With RIE, it is possible to generate anisotropic etching profiles; however, certain ion energy thresholds are often necessary to induce desired etching reactions and to control the etching profile. The ion energy thresholds often reduce etch selectivity and may damage the structure being etched.

Electron beams are another technology commonly used in the semiconductor and display manufacturing industries. Electrons beams, when utilized with suitable etching gas chemistries, can induce etching on a substrate. However, conventional electron beam etching apparatus typically emit an electron beam with a cross section on the micrometer scale, which is not practical for forming nanometer scale advanced devices.

Another issue materializes when utilizing conventional electron beam systems for etching angled trenches on large area substrates, such as those used for display devices. Typically, when forming angled trenches on a substrate, the electron beam source and the substrate are disposed at an angle relative to one another such that the substrate surface and the emitting surface of the electron beam source are nonparallel. However, in a scaled-up system for large area substrates, the angled arrangement of the electron beam source and the substrate creates a discrepancy in the distance between one end of the source to the substrate and the opposing end of the source to the substrate. The delta in distance is large enough such that etching across the surface of the large area substrate is non-uniform.

Accordingly, what is needed in the art are improved etching apparatus and methods.

### SUMMARY

In one embodiment, a chamber for electron beam etching is provided. The chamber includes a chamber body having sidewalls and a chamber bottom at least partially defining a process volume. One or more gas injectors are disposed in the chamber sidewalls and configured to provide process gases into the process volume. The chamber further includes a substrate support assembly having an insulating puck and a first electrode disposed within the insulating puck. A ceiling is coupled to the chamber body and supports one or more tracks thereon. A movable electrode assembly is coupled to the one or more tracks. The movable electrode assembly includes a second electrode, an insulating member coupled to the second electrode, and a backing plate coupled to the insulating member. The second electrode has a surface disposed at a nonparallel angle relative a major axis of the substrate support assembly. A bellows assembly is further disposed at one or more peripheral ends of the backing plate.

In one embodiment, a movable electrode assembly for electron beam etching is provided. The assembly includes a backing plate, an insulating member couple to the backing plate, and an electrode coupled to the insulating member. The electrode has a surface disposed at a nonparallel angle relative to the backing plate. One or more support members are further coupled to the backing plate, each having one or more wheels coupled to a track.

In one embodiment, a method of etching a substrate is provided. The method includes delivering a process gas to a process volume of a process chamber, applying an RF power to an electrode formed from a high secondary electron emission coefficient material disposed in the process volume, and generating a plasma comprising ions in the process volume. The electrode is bombarded with ions to cause the electrode to emit electrons from an electron emitting surface disposed at a nonparallel angle relative to an upper surface of a substrate. The emitted electrons are accelerated from the electrode through the plasma and toward the substrate to etch angled trenches in the substrate. The electrode is actuated through the process volume while etching the substrate.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings It is to be noted, however, that the appended drawings illustrate only exemplary embodiments and are therefore not to be considered limiting of its scope, and may admit to other equally effective embodiments.

FIG. 1 schematically illustrates an electron beam reactive plasma etching (EBRPE) apparatus according to an embodiment described herein.

FIG. 2 schematically illustrates an EBRPE apparatus according to an embodiment described herein.

FIG. 3 schematically illustrates an EBRPE apparatus according to an embodiment described herein.

FIG. 4 schematically illustrates an EBRPE apparatus according to an embodiment described herein.

FIGS. 5A and 5B schematically illustrate cross sectional views of a substrate at different stages of an electron beam reactive etching process using the EBRPE apparatus according to an embodiment described herein.

FIG. 6 schematically illustrates an EBRPE apparatus according to an embodiment described herein.

FIGS. 7A and 7B schematically illustrate cross sectional views of a substrate at different stages of an electron beam reactive etching process using the EBRPE apparatus according to an embodiment described herein.

FIG. 8 schematically illustrates an EBRPE apparatus according to an embodiment described herein.

FIGS. 9A and 9B schematically illustrate cross sectional views of a substrate at different stages of an electron beam reactive etching process using the EBRPE apparatus according to an embodiment described herein.

FIG. 10 schematically illustrates an EBRPE apparatus according to an embodiment described herein

FIG. 11 schematically illustrates a portion of an EBRPE apparatus according to an embodiment described herein.

FIG. 12 illustrates a process for performing an EBPRE process according to an embodiment described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein relate to apparatus and methods for performing electron beam reactive plasma etching. In one embodiment, an apparatus for performing EBRPE processes includes an electrode formed from a material having a high secondary electron emission coefficient. The electrode has an electron emitting surface disposed at a nonparallel angle relative to a major axis of a substrate assembly. The EBRPE apparatus may further comprise a capacitive or inductive coupled plasma generator. In another embodiment, methods for etching a substrate include generating a plasma and bombarding an electrode with ions from the plasma to cause the electrode to emit electrons. The electrons are accelerated toward a substrate to induce directional etching of the substrate. During the EBPRE process, the substrate or electrode is actuated through a process volume.

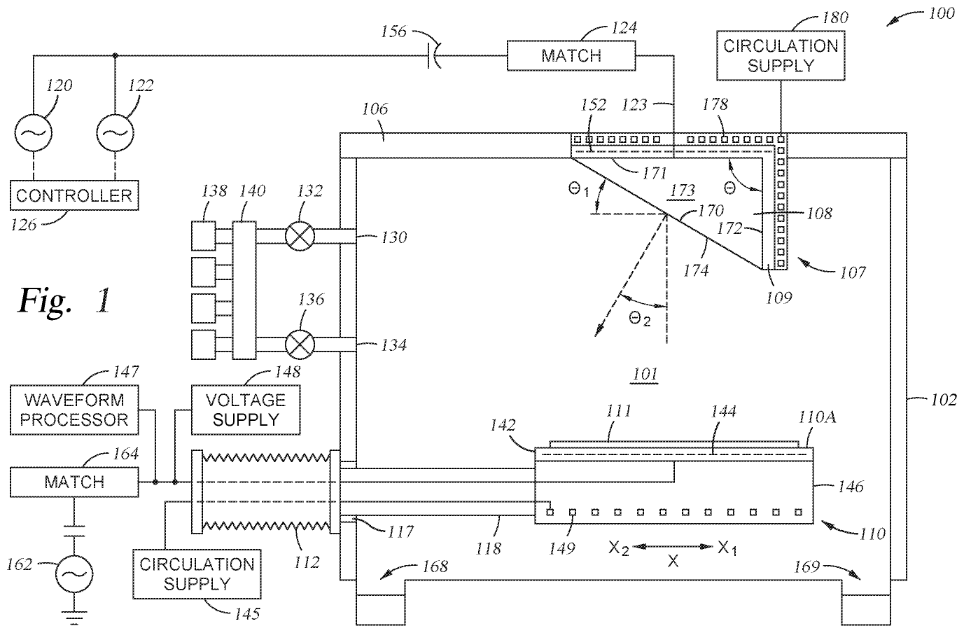

FIG. 1 schematically depicts an electron beam reactive etching (EBRPE) chamber 100. The chamber 100 has a chamber body 102 having sidewalls and a bottom at least partially defining a process volume 101. In one embodiment, the chamber body 102 has a polygonal shape, such as a cubic shape or the like. In another embodiment, the chamber body has a substantially cylindrical shape. The chamber body is fabricated from a material suitable for maintaining a vacuum pressure environment therein, such as metallic materials, for example aluminum or stainless steel.

A ceiling 106 is coupled to the chamber body 102 and further defines the process volume 101. In one embodiment, the ceiling 106 is formed from an electrically conductive material, such as the materials utilized to fabricate the chamber body 102. The ceiling 106 is coupled to and supports an electrode assembly 107 having a top electrode 108 coupled to an electrode insulator 109. In one embodiment, the electrode assembly 107 is coupled to the ceiling 106 such that the top electrode 108 is disposed adjacent the process volume 101. In one embodiment, two or more electrode assemblies 107 may be utilized in combination with EBRPE chamber 100. In another embodiment, a single electrode assembly 107 includes two or more top electrodes 108.

An RF power generator 120 (such as an RF source power) having a high frequency (e.g., greater than 60 MHz, such as 160 MHz) and an RF power generator 122 having a low frequency (e.g., less than 60 MHz, such as 10 MHz) are coupled to the top electrode 108 via an RF feed conductor 123. Output levels of the RF power generators 120, 122 are independently controlled by a controller 126. As will be described below, power from the RF power generators 120, 122 is coupled to the top electrode 108 through an impedance match 124.

Power, such as a RF source power, from the RF power generators 120, 122 is conducted through the ceiling 106 to the top electrode 108. In one embodiment, the chamber body 102 is maintained at ground potential. In one embodiment, grounded internal surfaces (i.e. chamber body 102) inside the chamber 100 are coated with a process compatible material such as silicon, carbon, silicon carbon materials, or silicon-oxide materials. In an alternative embodiment, grounded internal surfaces inside the chamber 100 are coated with a material such as aluminum oxide, yttrium oxide, or zirconium oxide.

In one embodiment, the RF power generators 120, 122 may be replaced by two high frequency power generators (not shown), or vice versa (e.g., two low RF frequency power generators), that are separately controlled. For example, a first high frequency power generator may have an output frequency in a lower portion (e.g., 30 MHz to 150 MHz) of a VHF band, while a second high frequency power generator may have an output frequency in an upper portion (e.g., 150 MHz to 300 MHz) of the VHF band. The controller 126 governs plasma ion density by selecting the ratio between the output power levels of the power generators 120, 122.

With the power generators 120, 122, radial plasma uniformity in the process volume can be controlled by selecting a distance between the top electrode 108 and a platform 110. In one example, the lower frequency produces an edge-high radial distribution of plasma ion density in the process volume 101 and the upper frequency produces a center-high radial distribution of plasma ion density. With a proper selection, the power levels from the power generators 120, 122 are capable of generating a plasma with a substantially uniform radial plasma ion density.

The top electrode 108 is formed from a conductive and process-compatible material having a high secondary electron emission coefficient, such as silicon, carbon, silicon carbon materials, silicon nitride materials, or metallic materials. In some embodiments, the top electrode 108 has one or more surfaces formed from an oxide material such as silicon oxide, aluminum oxide, magnesium oxide, tin oxide, yttrium oxide, or zirconium oxide. In one embodiment, the top electrode 108 has a triangular prism shape having two triangular base surfaces and three rectangular lateral surfaces. Stated differently, the top electrode 108 has a substantially three-dimensional and wedge-like shape. In one embodiment, the top electrode 108 may have a triangular right prism shape. It is contemplated, however, that the top electrode 108 may be formed of any suitable shape having a substantially planar electron emitting surface facing the process volume 101.

As depicted in FIG. 1, the top electrode 108 includes three lateral surfaces 170, 171, and 172, and two triangular base surfaces (one triangular base surface 173 is shown). Lateral surface 170 is disposed adjacent to and facing the process volume 101 and is hereafter described as the interior surface 170 of the top electrode 108. Interior surface 170 is substantially planar and is disposed at a nonparallel angle Θ₁ relative to a major axis X of the platform 110, thus enabling angled etching of a substrate 111 as further described below. The interior surface 170 is disposed at an angle Θ₁ between 0 degrees and 90 degrees relative to the major axis X, such as between 20 degrees and 70 degrees. For example, the interior surface 170 is disposed at an angle Θ₁ of between 35 degrees and 55 degrees relative to the major axis X of the platform 110. The angle Θ₁ of the interior surface 170 is selected on the basis of the desired etching angle of the substrate 111.

The electrode insulator 109 is coupled to the top electrode 108 along surfaces 171, 172, 173, and 174, and couples the top electrode 108 to the ceiling 106. The electrode insulator 109 may be formed of any suitable insulating material such as TFE, PEEK, ceramic, or the like. In one embodiment, an upper surface of the electrode insulator 109 is coupled to a lower surface of the ceiling 106 such that the electrode insulator 109 protrudes into the process volume 101. In another embodiment, the electrode insulator 109 is coupled to the lower surface of the ceiling such that the electrode insulator 109 is recessed into the lower surface of the ceiling 106. In yet another example, the electrode insulator 109 couples to the ceiling 106 at distal ends of the electrode insulator 109 such that the insulator 109 forms a central portion of the ceiling 106.

Vertical portions of the electrode insulator 109 couple to the surfaces 172, 173, and 174 of the top electrode 108 and adjoin an upper portion of the electrode insulator 109 coupled to the ceiling 106. In one embodiment, the upper portion of the electrode assembly 109 and a vertical portion coupled to the side 172 adjoin at an angle equal to the angle ϕ formed by adjacent surfaces 171, 172 of the top electrode 108. As depicted in FIG. 1, angle ϕ is a substantially right angle, and therefore, the portions of electrode insulator 109 coupled along the surfaces 171 and 172 are adjoined at a substantially right angle.

In one embodiment, the electrode insulator 109 contains a chucking electrode 152 facing the top electrode 108 and configured to chuck the top electrode 108 to the electrode insulator 109. The RF feed conductor 123 is connected to the chucking electrode 152 or any other suitable chamber components as needed. A D.C. blocking capacitor 156 is further connected in series with the power generators 120, 122. In such an embodiment, RF power from the RF feed conductor 123 is capacitively coupled from the chucking electrode 152 to the top electrode 108. In another embodiment, the electrode insulator 109 contains a vacuum chuck coupled to a vacuum pump (not shown) and configured to support the top electrode 108 by vacuum.

In one embodiment, the ceiling 106 and/or the electrode insulator 109 include internal passages 178 for circulating a thermally conductive liquid or media within. The thermal media circulation supply 180 acts as a heat sink or a heat source as needed. The mechanical contact between the top electrode 108 and the electrode insulator 109 is sufficient to maintain high thermal conductance between the top electrode 108 and electrode insulator 109 and/or the ceiling 106. In the embodiment of FIG. 1, the force of the mechanical contact is regulated by the electrostatic clamping force applied to the chucking electrode 152. In another embodiment, the force of the mechanical contact is regulated by vacuum chucking applied by a vacuum chuck (not shown) disposed in the electrode insulator 109.

The platform 110 is disposed in the process volume 101. The platform 110 supports the substrate 111 thereon and has a planar substrate support surface 110A oriented parallel to the major axis X. In one embodiment, the platform 110 is coupled to a shaft 118 disposed through an opening 117 in the sidewall of the chamber body 102. The platform 110 is movable in either a first or a second axial direction X₁ or X₂, parallel to the major axis X, by a servo 112 coupled to the shaft 118. The platform 110 is supported within the process volume 101 such that the substrate support surface 110A is disposed at a distance of between about 0.5 cm and about 1 m, such as between about 5 cm and about 90 cm, from a bottom end of the top electrode 108. For example, the substrate support surface 110A is disposed at a distance of between about 20 cm and about 80 cm, such as between about 40 cm and about 60 cm, from a bottom end of the top electrode 108.

In one embodiment, the platform 110 includes an insulating layer 142 which forms the substrate support surface 110A, an electrode 144 disposed inside the insulating layer 142, and a chucking voltage supply 148 connected to the electrode 144. Additionally, a base layer 146 underlying the insulating layer 142 has internal passages 149 for circulating a thermal transfer medium (e.g., a liquid) from a circulation supply 145. In one embodiment, the circulation supply 145 functions as a heat sink. In another embodiment, the circulation supply 145 functions as a heat source. In one embodiment, a temperature of the platform 110 is maintained between about 20° C. and about 1000° C., such as about 100° C. and about 700° C., for example between about 200° C. and about 500° C.

In one embodiment, an RF bias power generator 162 is coupled through an impedance match 164 to the electrode 144 of the platform 110. In a further embodiment, a waveform tailoring processor 147 may be connected between the output of the impedance match 164 and the electrode 144. The waveform tailoring processor 147 changes the waveform produced by the RF bias power generator 162 to a desired waveform. The ion energy of plasma near the substrate 111 is controlled by the waveform tailoring processor 147. In one embodiment, the waveform tailoring processor 147 produces a waveform in which the amplitude is held during a certain portion of each RF cycle at a level corresponding to a desired ion energy level. The controller 126 controls the waveform tailoring processor 147.

First gas injectors 130 provide process gas into the process volume 101 through a first valve 132. Additionally or alternatively, second gas injectors 134 provide process gas into the process volume 101 through a second valve 136. In one embodiment, the first gas injectors 130 and/or the second gas injectors 134 are disposed in the sidewalls of the chamber body 102. In another embodiment, the first gas injectors 130 and/or the second gas injectors 134 are disposed in the ceiling 106. In another embodiment, the first gas injectors 130 are disposed in the ceiling 106 and the second gas injectors are disposed in the sidewalls of the chamber body 102. In yet another embodiment, the first gas injectors 130 and/or the second gas injectors 134 are disposed through the electrode assembly 107 and top electrode 108.

Gas is supplied from an array of gas supplies 138 through an array of valves 140 which may include the first and second valves 132 and 136. In one embodiment, gas species and gas flow rates delivered into the process volume 101 are independently controllable. For example, gas flow through the first gas injectors 130 may be different from the gas flow through the second gas injectors 134. The controller 126 governs the array of valves 140 to control the gas flow into the processing chamber 100.

In one embodiment, an inert gas, such as argon or helium, is supplied into the process volume 101 through the first gas injectors 130 and a process gas is supplied into the process volume 101 through the second gas injectors 134, or vice versa. In this embodiment, the inert gas delivered to the process volume 101 adjacent the top electrode 108 functions to buffer the top electrode 108 from a reactive plasma formed in the process volume 101, thus increasing the operating life of the top electrode 108. In another embodiment, process gas is supplied to the process volume 101 through both the first gas injectors 130 and the second gas injectors 134. Process gases may be supplied to the process volume 101 such that the process gases do not traverse or affect the electron beam pathway.

In one embodiment, plasma is generated in the process volume 101 by various bulk and surface processes, for example, by capacitive coupling. In one embodiment, plasma generation is also facilitated by energetic ion bombardment of the interior surface 170 of the electron-emitting top electrode 108. In one embodiment, a bias power applied to the top electrode 108 is between about 1 KW and about 10 KW with a frequency of between about 400 kHz and about 200 MHz. It is believed that ions generated by a capacitively coupled plasma are influenced by an electric field that encourages bombardment of the top electrode 108 by the ions generated from the plasma.

The ion bombardment energy of the top electrode 108 and the plasma density are functions of both RF power generators 120 and 122. The ion bombardment energy of the top electrode 108 is substantially controlled by the lower frequency power from the RF power generator 122 and the plasma density in the process volume 101 is substantially controlled by the higher frequency power from the RF power generator 120. It is believed that ion bombardment of the top electrode 108 causes the electrode to emit secondary electrons from the interior surface 170. Energetic secondary electrons, which have a negative charge, are emitted from the interior surface 170 of the top electrode 108 and accelerated away from the electrode due to the negative bias of the top electrode 108.

The flux of energetic electrons from the emitting surface of the top electrode 108 is believed to be an electron beam, and is oriented in a predetermined angle. In one embodiment, the trajectory of the electron beam may be oriented substantially perpendicular to the interior surface 170 of the top electrode 108. Because the interior surface 170 is angled relative to the major axis X of the platform 110, the electron beam may be emitted at an angle Θ₂ relative to the normal of an upper surface of the substrate 111 during etching. For example, the electron beam may be emitted from the interior surface 170 at an angle Θ₂ of between 0 degrees and 90 degrees relative to the normal of the upper surface of the substrate 111, such as between 30 degrees and 60 degrees. For example, the electron beam may be emitted at an angle Θ₂ of between 40 degrees and 50 degrees. In embodiments wherein the trajectory of the electron beam is oriented substantially perpendicular to the interior surface 170, a magnitude of angle Θ₂ may be substantially equal to a magnitude of angle Θ₁.

A beam energy of the electron beam is approximately equal to the ion bombardment energy of the top electrode 108, which can typically range from about 10 eV (electron volts) to 20,000 eV. In one embodiment, the plasma potential is greater than the potential of the top electrode 108 and the energetic secondary electrons emitted from the top electrode 108 are further accelerated by a sheath voltage of the plasma as the secondary electrons traverse through the plasma in the process volume 101.

At least a portion of the electron beam, comprised of the secondary electron flux emitted from the top electrode 108 due to energetic ion bombardment of the electrode interior surface 170, propagates through the process volume 101 and reacts with process gases near the substrate 111. With utilization of suitable process gases, such as chlorine containing materials, fluorine containing materials, bromine containing materials, oxygen containing materials, and the like, the electron beam induces angled etching reactions on the substrate 111. It is believed that the electron beam, in addition to the capacitively generated plasma, generates chemically reactive radicals and ions which adsorb to the surface of the substrate 111 and form a chemically reactive polymer layer of the surface of the substrate 111. The electron beam bombardment of the chemically reactive polymer layer causes generation of volatile products which results in angled etching (material removal) of the substrate 111.

Accordingly, the electron beam induces chemical reactions to liberate gas phase volatile products and etch the substrate 111. Etching of the substrate 111 is also influenced by other factors, such as pressure. In one embodiment, a pressure maintained in the process volume 101 during electron beam etching of the substrate 111 is between about 0.001 Torr and about 10 Torr. The pressure is generated by one or more vacuum pumps 168, 169 which are in fluid communication with the process volume 101. The pressure is regulated by gate valves (not shown) disposed between the process volume 101 and the vacuum pumps 168, 169.

During etching, the formation of angled trenches on the substrate 111 is a result of the angled and nonparallel orientation of electron beam emitting interior surface 170 relative to the major axis X of the platform 110. However, an issue of etching uniformity arises from secondary electron flux non-uniformity, partially caused by the tilted orientation of the interior surface 170 as well as electron beam divergence. Thus, in order to compensate for the secondary electron flux non-uniformity, the platform 110 is actuated across the process volume 101 by the servo 112 to move the substrate 111 relative to the top electrode 108 during etching. The substrate 111 may be actuated in either the first or second axial direction X₁ or X₂. By moving the substrate 111 in a direction parallel to the major axis X, the effects of any secondary electron flux non-uniformity may be substantially diminished or eliminated, as the movement of the substrate 111 produces averaging of the exposure period of the substrate 111 to different portions of the electron beam.

Although the EBRPE chamber 100 is depicted with the platform 110, any substrate support assembly or transport mechanism described herein may be utilized in combination with the features of EBRPE chamber 100.

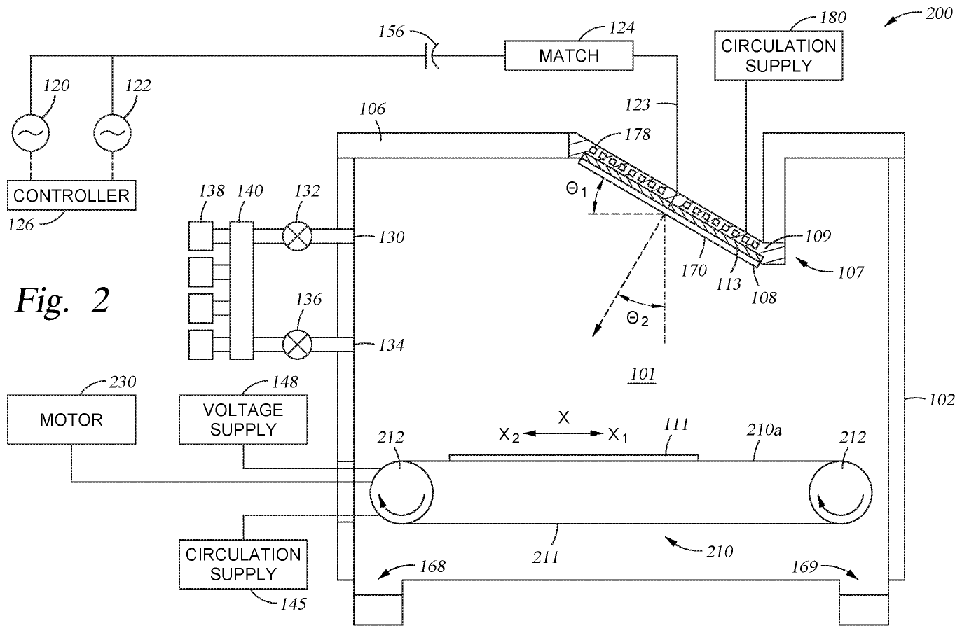

FIG. 2 schematically depicts another embodiment of an EBRPE chamber 200. The EBRPE chamber 200 is similar to chamber 100 described above, but includes the electrode assembly 107 having a substantially plate-like top electrode 108 coupled to the electrode insulator 109. In one embodiment, the top electrode 108 is a shallow cuboid shape. Similar to the embodiment in FIG. 1, the top electrode 108 is formed from a conductive and process-compatible material having a high secondary electron emission coefficient, such as silicon, carbon, silicon carbon materials, silicon nitride materials, or metallic materials. In some embodiments, the top electrode 108 has one or more surfaces formed from an oxide material such as silicon oxide, aluminum oxide, magnesium oxide, tin oxide, yttrium oxide, or zirconium oxide. The thickness of the top electrode 108 is material-dependent. It is contemplated, however, that the top electrode 108 has a thickness of between about 0.5 and about 5 inches, for example, about 1 inch. In one embodiment, a second electrode plate 113 is disposed between the top electrode 108 and the insulator 109 to provide mechanical support and electrical coupling. The second electrode plate 113 is formed of a conductive material, such as aluminum or the like. In such an embodiment, RF power from the RF feed conductor 123 is capacitively coupled from the second electrode plate 113 to the top electrode 108. In one embodiment, a thermal or electrical shim (not shown) is further disposed between the second electrode plate 113 and the top electrode 108.

The top electrode 108 is disposed in an angled and nonparallel orientation relative to a major axis X of a conveyor system 210. In one embodiment, both the top electrode 108 and the electrode insulator 109 are disposed in an angled or tilted orientation relative to the major axis X. The top electrode 108, and thus the interior surface 170, is disposed at an angle Θ₁ between 0 degrees and 90 degrees relative to the major axis X, such as between 20 degrees and 70 degrees. For example, the top electrode 108 is disposed at an angle Θ₁ between 35 degrees and 55 degrees relative to the major axis X.

The angled and nonparallel orientation of the top electrode 108, and ultimately the interior surface 170, enables angled etching of the substrate 111. Because the interior surface 170 is angled relative to the major axis X, the electron beam may be emitted at an angle Θ₂ relative to the normal of the upper surface of the substrate 111 during etching. For example, the electron beam may be emitted from the interior surface 170 at an angle Θ₂ of between 0 degrees and 90 degrees relative to the normal of the upper surface of the substrate 111, such as between 25 degrees and 75 degrees. For example, the electron beam may be emitted at an angle Θ₂ of between 35 degrees and 55 degrees. In embodiments wherein the trajectory of the electron beam is oriented substantially perpendicular to the interior surface 170, the magnitude of angle Θ₂ may be substantially equal to the magnitude of angle Θ₁. In some embodiments, the angle of tilt of the electrode 108 corresponds with the angle of trajectory of the electron beam in an analogous manner.

In one embodiment, the electrode insulator 109 couples to the ceiling 106 at vertically unaligned junctions to form the tilted orientation of electrode assembly 107. In such an embodiment, a portion of the ceiling 106 may vertically extend into the process volume 101, wherein a bottom end of the electrode insulator 109 may couple thereto. In another embodiment, the electrode insulator 109 couples to the ceiling 106 at vertically aligned junctions. In some embodiments, the electrode insulator 109 may couple to the ceiling 106 at fixed points. Alternatively, the coupling of electrode insulator 109 to the ceiling 106 may be adjustable, enabling variable tilting of the electrode assembly 107 relative to the major axis X.

The conveyor system 210 is disposed in the process volume 101 and is configured to support and move the substrate 111. The conveyor system 210 includes a belt 211 having an upper substrate support surface 210a. The upper substrate support surface 210a is substantially planar and parallel to the major axis X of the conveyor system 210. The belt 211 may be disposed around one or more rollers 212 configured to support the belt 211 such that the substrate support surface 210a is disposed at a distance of between about 0.5 cm and about 1 m, such as between about 5 cm and about 90 cm, from the bottom end of the top electrode 108. For example, the upper substrate support surface 210A is disposed at a distance of between about 20 cm and about 80 cm, such as between about 40 cm and about 60 cm, from a bottom end of the top electrode 108. A drive motor 230 is coupled to the one or more rollers 212 to move the belt 211 in a clockwise or counterclockwise direction, enabling the substrate 111 to be moved in either a first or second axial direction X₁ or X₂, parallel to the major axis X. In some embodiments, two or more conveyor systems 210 may be disposed in the process volume 101 and oriented in substantially divergent axial lines, thus allowing the substrate 111 to be moved in more than two axial directions.

In one embodiment, the conveyor system 210 includes one or more chucking electrodes (not shown) disposed in the belt 211 and a chucking voltage supply 148 connected to the electrodes. The chucking voltage supply 148 supplies a voltage power to the one or more chucking electrodes to hold the substrate 111 against the substrate support surface 210a.

The conveyor system 210 further includes internal passages for circulating a thermal transfer medium from a circulation supply 145. In one embodiment, the circulation supply 145 functions as a heat sink. In another embodiment, the circulation supply 145 functions as a heat source. In one embodiment, a temperature of the conveyor system 210 is maintained between about 20° C. and about 1000° C., such as about 100° C. and about 700° C., for example between about 200° C. and about 500° C.

As described above, the angled and nonparallel orientation of the top electrode 108, in addition to other factors such as electron beam divergence, may result in a non-uniform etching profile across the substrate 111. In order to compensate for this secondary electron flux non-uniformity, the substrate 111 is moved across the process volume 101 by the conveyor system 210 in an axial direction parallel to the major axis X. By moving the substrate 111 in either the first or second axial direction X₁ or X₂, the non-uniform etching may be blurred or averaged in a controlled manner.

Although the EBRPE chamber 200 is depicted with the conveyor system 210, any substrate support assembly or transport mechanism described herein may be utilized in combination with the features of EBRPE chamber 200.

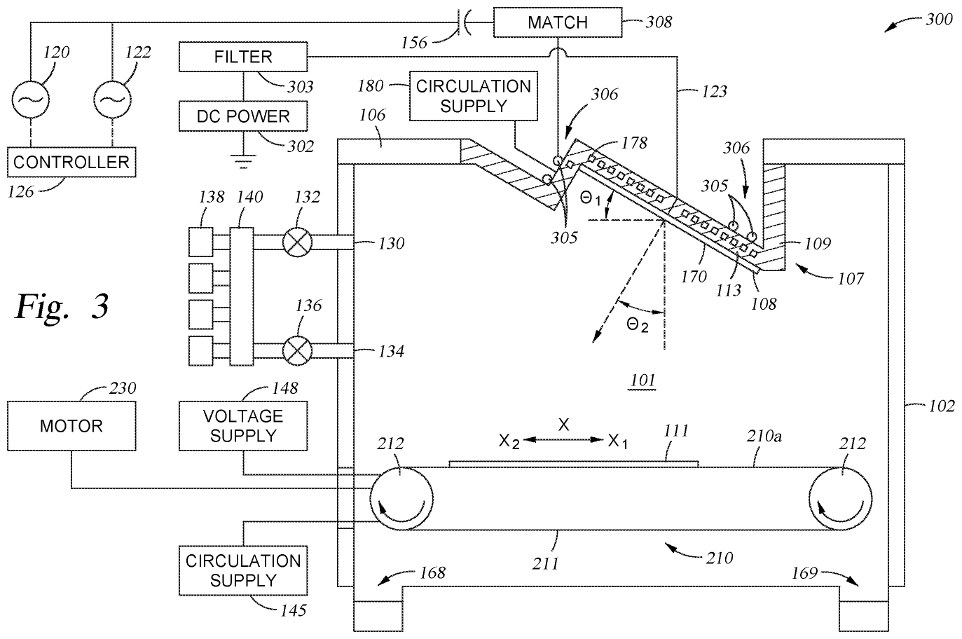

FIG. 3 depicts another embodiment of an EBRPE chamber 300. The EBRPE chamber 300 is similar to the chambers 100, 200 described above, but includes a plasma source coil assembly 306 disposed adjacent the top electrode 108 to form an inductively coupled plasma (ICP) during etching. The plasma source coil assembly 306 includes one or more inductive coil antennas 305 driven by RF power generators 120, 122 through an impedance match 308. The one or more inductive coil antennas 305 may be formed of any suitable shape and conductive material. For example, the inductive coil antennas 305 are toroidal tubes having a circular cross-section. In another example, the inductive coil antennas 305 are spiraling tubes having a rectangular cross-section. In one embodiment, the inductive coil antennas 305 are formed of a copper tube having a silver coating formed thereon. The inductive coil antennas 305 may be cooled by any suitable heat exchange mechanism, including but not limited to circulated thermal transfer media.

The RF power generator 120 having a high frequency (e.g., greater than 60 MHz, such as 160 MHz) and the RF power generator 122 having a low frequency (e.g., less than 60 MHz, such as 10 MHz) are coupled to the one or more inductive coil antennas 305 via an RF feed conductor 123. Output levels of the RF power generators 120, 122 are independently controlled by a controller 126. The inductive coil antennas 305 generate ICP when a power voltage is applied through the RF power generator 120, 122. The controller 126 governs inductive coil plasma density by selecting the ratio of out power levels between power generators 120 and 122.

A DC power generator 302 is also coupled to the EBRPE chamber 300. The DC power generator 302 supplies a DC voltage power to the top electrode 108 through a low pass filter 303. In one example, the DC power generator supplies a negative DC voltage to the top electrode 108. In one embodiment, the DC power is applied to the top electrode 108 in a pulsed manner. In another embodiment, the DC power is applied to the top electrode 108 in a continuous manner. When applying the negative voltage from the DC power generator 302, the negative DC voltage may increase the ion bombardment energy and further enhance the secondary electron emission from the top electrode 108. In such an embodiment, the RF power supplied to the plasma source coil assembly 306 from the RF power generators 120, 122 is predominantly used to generate plasma in the EBRPE chamber 300, while the negative DC power supplied to the top electrode 108 from the DC power generator 302 assists in accelerating the secondary electrons toward the substrate 111 so as to efficiently induce etching. It is believed that the negative DC power from the DC power generator 302 combined with the RF power from the RF power generators 120, 122 increases the plasma sheath voltage generated, which may assist the flux of the secondary electrons as generated so as to enhance the etching performance on the substrate 111.

Similar to the EBRPE chamber 200, the conveyor system 210 of EBRPE chamber 300 is configured to move the substrate 111 through the process volume 101 in an axial direction parallel to the major axis X. The conveyor system 210 moves the substrate 111 in either a first or second axial direction X₁ or X₂ in order to average any non-uniform etching caused by non-uniform secondary electron flux of the electron beam emitted from the top electrode 108.

Although the EBRPE chamber 300 is depicted with the conveyor system 210, any substrate support assembly or transport mechanism described herein may be utilized in combination with the features of EBRPE chamber 300.

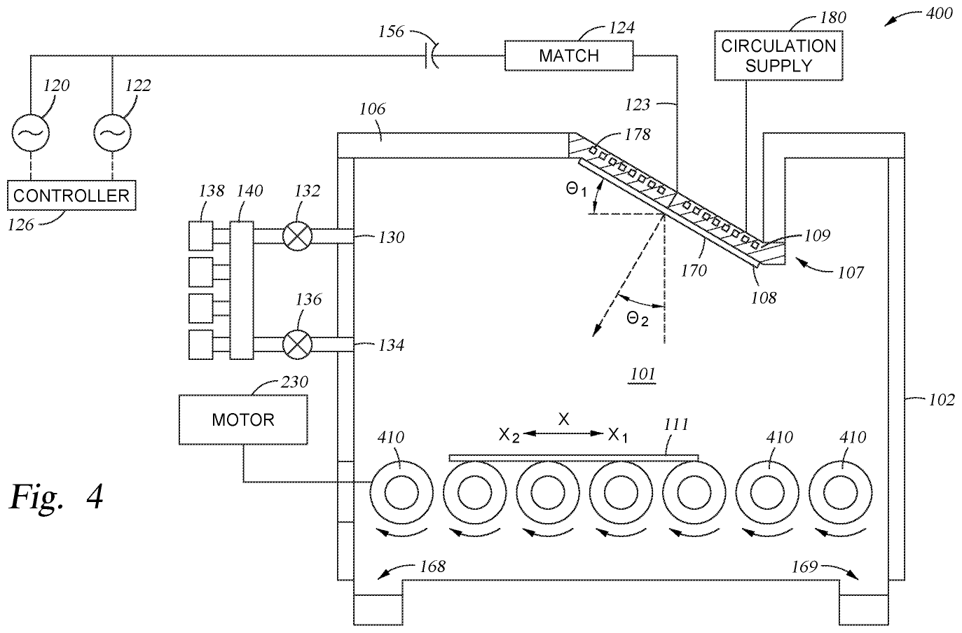

FIG. 4 depicts another embodiment of an EBRPE chamber 400. The EBRPE chamber 400 is similar to the chambers 100, 200, and 300 described above, but includes a plurality of transport rollers 410 configured to move the substrate 111 through the process volume 101 in a direction parallel to a major axis X of the rollers 410. The rollers 410 are formed of any suitable material that has a sufficient chemical resistance to the etch process and will not damage the substrate 111 during movement. For example, the rollers 410 may be formed of aluminum, aluminum oxide, or any suitable metals or elastomers which are resistant to the etch process.

Any suitable number of rollers 410 may be utilized in the EBRPE chamber 400 (six rollers are depicted). In one embodiment, each roller of the plurality of rollers 410 has the same diameter size. In another embodiment, one or more of the plurality of rollers 410 have different diameter sizes. Furthermore, the plurality of rollers 410 may be disposed within the process volume 101 such that each of the rollers 410 is equidistant from an adjacent roller 410. Alternatively, one or more rollers 410 may be disposed at unequal distances from each other.

The plurality of rollers 410 support the substrate 111 thereon and may be disposed within the chamber process volume 101 such that the substrate 111 is disposed at a distance of between about 0.5 cm and about 1 m, such as between about 5 cm and about 90 cm, from the bottom end of the top electrode 108 during etching. For example, the substrate 111 is disposed at a distance of between about 20 cm and about 80 cm, such as between about 40 cm and about 60 cm, from a bottom end of the top electrode 108.

A drive motor 430 is coupled to the plurality of rollers 410 to move the rollers 410 in a clockwise or counterclockwise direction, thus enabling the substrate 111 to be moved in either a first or second axial direction X₁ or X₂ through the process volume 101. The plurality of rollers 410 is utilized to move the substrate 111 in either a first or second axial direction X₁ or X₂, parallel to the major axis X, in order to average any non-uniform etching caused by non-uniform secondary electron flux of the electron beam emitted from the top electrode 108.

Although the EBRPE chamber 400 is depicted with the plurality of rollers 410, any substrate support assembly or transport mechanism described herein may be utilized in combination with the features of EBRPE chamber 400.

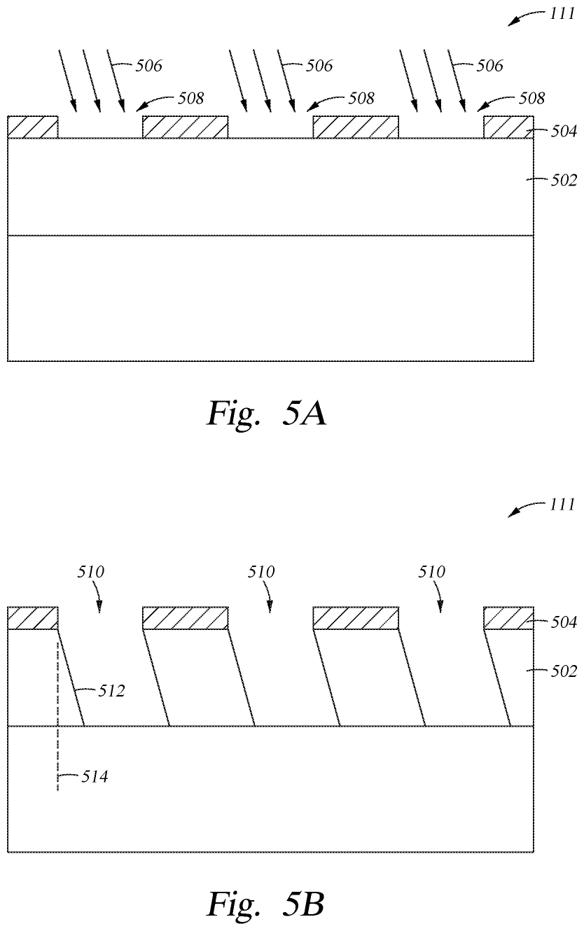

FIG. 5A depicts the substrate 111 positioned in a chamber having a single top electrode 108 or a chamber having multiple electrodes 108 oriented at the same nonparallel angle relative to the substrate 111, such as chambers 100, 200, 300, or 400 described above. In operation, the angled and nonparallel orientation of the electrodes 108 alters the angle of trajectory through the process volume 101 of the electron beam 506 having a predetermined angle of emission. In one embodiment, the electron beam 506 has a predetermined angle of emission substantially perpendicular to the interior surface 170 of the top electrode 108. As a result, the electron beam 506 may etch the material layer 502 disposed on the substrate 111 and exposed by the openings 508 defined by the patterned mask layer 504 with an incident or tilt angle, as shown in FIG. 5A.

After a predetermined period of processing time, a feature 510 with a sloped sidewall 512 may be formed in the material layer 502, as shown in FIG. 5B. The sloped sidewall 512 may have a desired angle relative to a vertical plane 514. In one example, the angle is between about 0 degrees and about 90 degrees relative to the vertical plane 514, such as between about 10 degrees and about 80 degrees. In another example, the angle is between about 30 degrees and about 60 degrees relative to the vertical plane 514. It is noted that the directional electron beam 506 may be utilized to create the sloped sidewall 512 in the material layer 502. Alternatively, the electron beam may be utilized to trim and reduce the dimensions of the mask layer 504.

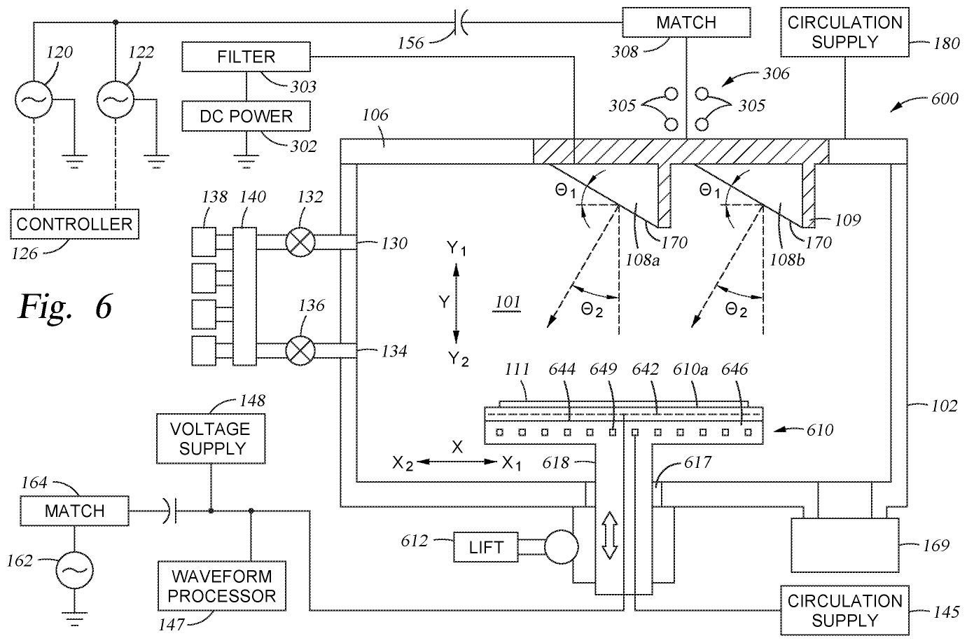

FIG. 6 depicts another embodiment of an EBRPE chamber 600. The EBRPE chamber 600 is similar to the chambers 100, 200, 300, and 400, but includes a pedestal 610 disposed in the process volume 101. Furthermore, a single electrode assembly 107 having two triangular prism top electrodes 108 is depicted. As discussed above, any suitable number and shape of electrode assemblies 107, top electrodes 108, and combinations thereof may be utilized. For example, two or more triangular prism top electrodes 108 may be coupled to a single electrode insulator 109. In another example, two or more plate-like top electrodes 108 may each be coupled to a separate and distinct electrode insulator 109. As depicted in FIG. 6, the interior surface 170 of each top electrode 108 is tilted at a nonparallel angle Θ₁ relative to a major axis X of a pedestal 610. The utilization of two or more top electrodes 108 enables increased efficiency during EBRPE processes, allowing more features to be simultaneously etched into the substrate 111.

EBRPE chamber 600 is depicted as having a plasma source coil assembly 306 disposed adjacent the top electrodes 108 and coupled to the RF power generators 120, 122 through an impedance match 308. The independently controlled RF power generators 120, 122 supply a power voltage to one or more inductive coil antennas 305 to generate an ICP within the process volume 101. Additionally, a DC power generator 302 is coupled to each of the top electrodes 108. The DC power generator 302 supplies a DC voltage power to the top electrodes 108 to assist in accelerating the secondary electrons toward the substrate 111 so as to efficiently induce etching. In another embodiment, the top electrodes 108 are capacitively coupled to the RF power generators 120, 122 to generate a capacitively coupled plasma within the process volume.

The pedestal 610 is disposed in the process volume 101. In one embodiment, the pedestal 610 is coupled to a shaft 618 disposed through an opening 617 in the bottom of the chamber body 102. The pedestal 610 supports the substrate 111 thereon and has a substrate support surface 610a oriented parallel to the ceiling 106 and the major axis X. In one embodiment, the pedestal 610 is movable by a lift mechanism 612 in a first or second axial direction Y₁ or Y₂, parallel to a major axis Y and perpendicular to the major axis X. During operation, the substrate support surface 610a is maintained at a distance of between about 1 cm and about 130 cm, such as between about 10 cm and about 100 cm, from the bottom ends of the top electrodes 108. For example, the substrate support surface 610a is maintained at a distance of between about 20 cm and about 80 cm, such as a distance of between about 40 cm and 60 cm, from the bottom ends of the top electrodes 108.

In one embodiment, the pedestal 610 includes an insulating puck 642 which forms the substrate support surface 610a, an electrode 644 disposed inside the insulating puck 642, and a chucking voltage supply 148 electrically coupled to the electrode 144. In one embodiment, an RF bias power generator 162 is coupled through an impedance match 164 to the electrode 644 of the pedestal 610. In a further embodiment, a waveform tailoring processor 147 may be connected between the output of the impedance match 164 and the electrode 644. The controller 126 controls the waveform tailoring processor 147. Additionally, a base layer 646 underlying the insulating puck 642 has internal passages 649 for circulating a thermal transfer medium (e.g., a liquid) from a circulation supply 145. In one embodiment, the circulation supply 145 functions as a heat sink. In another embodiment, the circulation supply 145 functions as a heat source. In one embodiment, a temperature of the pedestal 610 is maintained between about −20° C. and about 1000° C.

During etching, the lift mechanism 612 actuates the pedestal 610 in the first or second axial direction Y₁ or Y₂. The vertical movement of the pedestal 610 enables the formation of angled features across the surface of substrate 111 having different depths. By controlling the position and speed of the pedestal 610 along the major axis Y during etching, the residence time of the electron beam at different positions along the surface of the substrate 111 may be effectively controlled. Thus, etch depth is modulated across the substrate surface as a function of the vertical position and velocity of the substrate 111.

Although the EBRPE chamber 600 is depicted with the pedestal 610, any substrate support assembly or transport mechanism described herein may be utilized in combination with the features of EBRPE chamber 600.

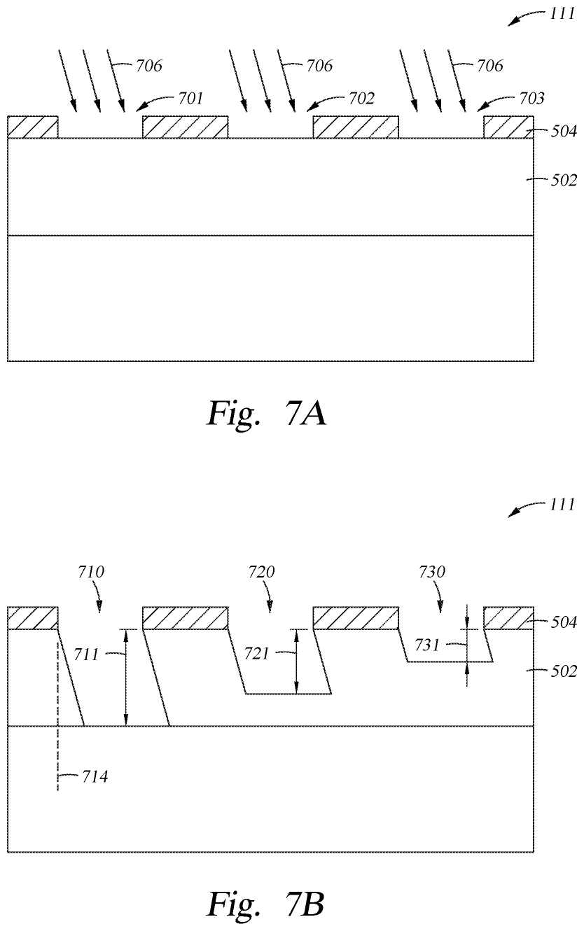

FIG. 7A depicts the substrate 111 positioned in a chamber having a single top electrode 108 or a chamber having multiple electrodes 108 oriented at the same nonparallel angle relative to the substrate 111, such as the chambers 100, 200, 300, 400, and 600 described above. In operation, the angled and nonparallel orientation of the electrode 108 alters the angle of trajectory through the process volume 101 of the electron beam 706 having a predetermined angle of emission. As a result, the electron beam 706 may etch the material layer 502 disposed on the substrate 111 and exposed by the openings 701, 702, and 703 defined by the patterned mask layer 504 with an incident or tilt angle relative to a vertical plane 714, as shown in FIG. 7A.

After a predetermined period of processing time at each opening 701, 702, and 703 on the substrate 111, features 710, 720, and 730 having desired depths 711, 721, and 731 may be formed in the material layer 502, as shown in FIG. 7B. The depths 711, 721, and 731 are a function of the residence time of the electron beam 706 at each location 701, 702, and 703, which is controlled by modulating the velocity of the substrate 111 along a vertical axis. Increasing the velocity of the substrate 111 effectively decreases residence time of the electron beam at any given point on the substrate 111, whereas decreasing the velocity or stopping movement altogether effectively increases the residence time at a given point. For example, when starting with the pedestal 610 at a lowered position, the velocity of the substrate 111 may be progressively increased in the Y₁ direction in order to form the features 710, 720, and 730, respectively. Alternatively, when starting with the pedestal 610 at a raised position, the velocity of the substrate 111 may be progressively decreased in the Y₂ direction to form the features 710, 720, 730, respectively.

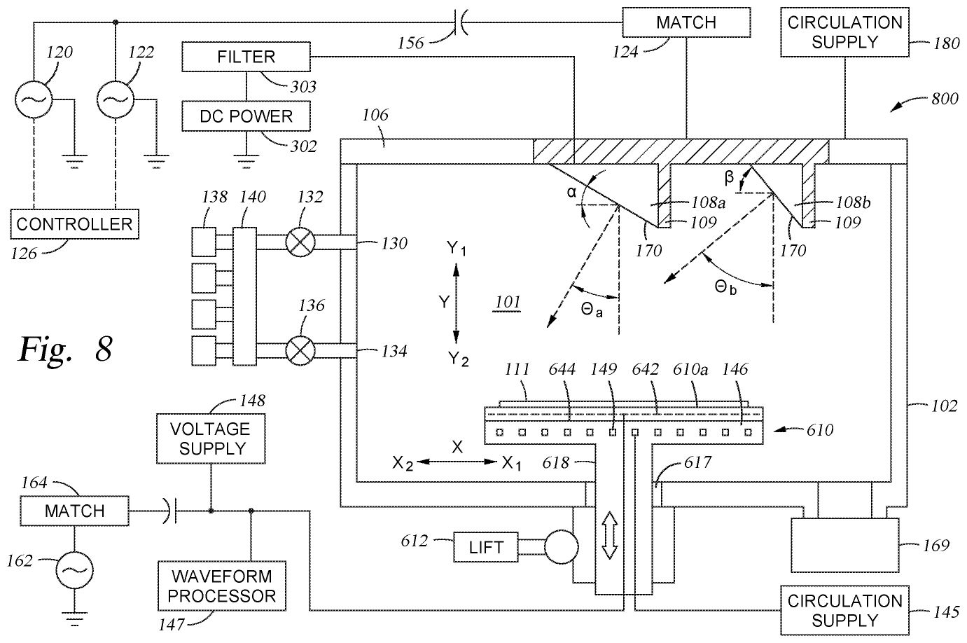

FIG. 8 depicts another embodiment of an EBRPE chamber 800. The EBRPE chamber 800 is similar to the chamber 600, but includes two or more top electrodes 108 coupled to RF power generators 120, 122 and having two or more interior surfaces 170 oriented at different nonparallel angles relative to each other and the major axis X. For example, a first top electrode 108a may have an interior surface 170a with a first nonparallel angle of tilt a, and a second top electrode 108b may have an interior surface 170b with a second nonparallel angle of tilt 13. Electron beams emitted from each of the top electrodes 108a, 108b therefore have different angles of trajectory through the process volume 101 and different angles of incidence upon contact with the substrate 111 during etching. For example, the electron beam emitted from top electrode 108a has a trajectory angle Θₐ relative to the normal of the top surface of the substrate 111, whereas the top electrode 108b has a trajectory angle Θ_{b} relative to the normal of the top surface of the substrate 111. This enables the formation of features on the substrate 111 having different slopes, as described below.

Although the EBRPE chamber 800 is depicted with the pedestal 610, any substrate support assembly or transport mechanism described herein may be utilized in combination with the features of EBRPE chamber 800.

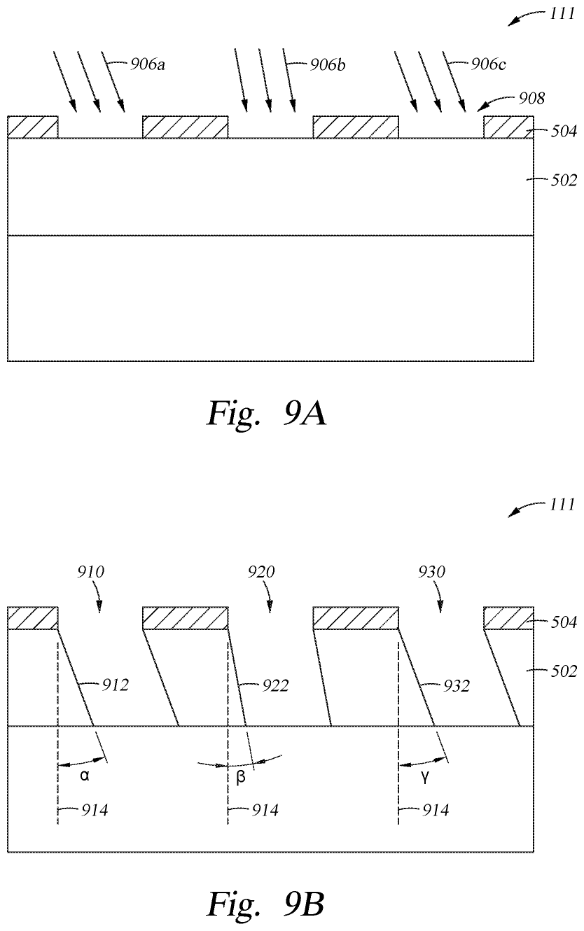

FIG. 9A depicts the substrate 111 positioned in a chamber having two or more electrodes 108 oriented at different nonparallel angles relative to each other, such as chamber 800 described above. Each top electrode 108 in the chamber 800 emits an electron beam 906 having a predetermined angle of emission (three beams 906a, 906b, and 906c are shown in FIG. 9A). In one embodiment, each electron beam 906 has a predetermined angle of emission substantially perpendicular to the interior surface 170 it was emitted from. As a result, each of the electron beams 906a-c may etch the material layer 902 disposed on the substrate 111 and exposed by the openings 908 defined by the patterned mask layer 904 with a different incident or tilt angle, as shown in FIG. 9A.

After a predetermined period of the processing time, features 910, 920, and 930 having sidewalls 912, 922, and 932, respectively, may be formed in the material layer 902, as shown in FIG. 9B. The sloped sidewalls 912, 922, and 932, may each have a desired angle relative to a vertical plane 914 and to each other. In one embodiment, each sidewall 912, 922, and 932 has a different desired angle (a, 13, y, respectively) relative to the others. In another embodiment, one or more sidewalls 912, 922, and 932 have a different desired angle relative to the others. In one embodiment, each angle is between about 0 degrees and about 90 degrees relative to the vertical plane 914. The formation of sidewalls having different desired angles is a function of the chamber having two or more electrode interior surfaces tilted at different angles relative to one another.

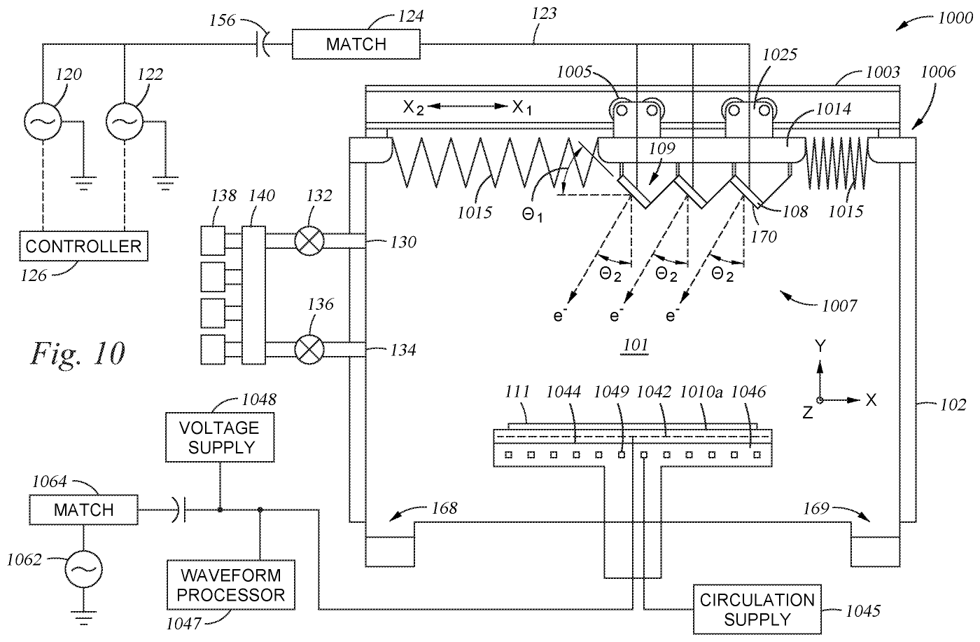

FIG. 10 depicts another embodiment of an EBRPE chamber 1000. The EBRPE chamber 1000 is similar to the chambers 100, 200, 300, 400, 600, and 800 described above, but includes a moving electrode assembly 1007 coupled to the ceiling 1006. In one embodiment, the moving electrode assembly 1007 is utilized as an alternative to the moving substrate support assemblies described above, such as those depicted in chambers 100, 200, 300, 400, 600, and 800. In another embodiment, the moving electrode assembly 1007 is utilized in combination with the moving substrate support assemblies described above.

The moving electrode assembly 1007 is movably coupled to one or more tracks 1003. The track 1003 may be any suitable type of track, including but not limited to a box track, a flat track, a single rail track, or the like. According to the embodiment depicted in FIG. 10, the track 1003 is disposed outside of the process volume 101 and adjacent to the chamber body 102. In other embodiments, the track 1003 is disposed inside the process volume 101 and supported by the ceiling 1006. The moving electrode assembly 1007 couples to the track 1003 via one or more support members 1025, each having one or more wheels 1005 configured to roll along a flange or guideway (not shown) of the track 1003. In some embodiments, the support members 1025 include one or more wheels configured to roll along multiple sides of the track 1003, such as underfriction wheels or side friction wheels. In another embodiment, the track 1003 may be a maglev track having magnetized coils configured to support the moving electrode assembly 1007 by repelling and attracting magnets disposed on the moving electrode assembly 1007. It is contemplated that any suitable moving mechanism may be utilized to movably couple the moving electrode assembly 1007 to the track 1003.

As depicted in FIG. 10, the moving electrode assembly 1007 includes one or more top electrodes 108 coupled to one or more electrode insulators 109 and a backing plate 1014. In one embodiment, the top electrodes 108 are capacitively coupled to the RF power generators 120, 122 through the backing plate 1014 to facilitate capacitively coupled plasma formation within the process volume 101 and ion bombardment of the interior surfaces 170 of the top electrodes 108. In another embodiment, the chamber 1000 includes a plasma source coil assembly (not shown) disposed adjacent to or on the moving electrode assembly 1007. The plasma source coil assembly includes one or more inductive coil antennas coupled to RF power generators 120, 122 and configured to generate an inductively coupled plasma. Similar to the embodiments described above, the interior surfaces 170 of the top electrodes 108 are disposed in a nonparallel and angled orientation relative to a planar upper surface 1010a of a substrate support assembly 1010 disposed in the process volume 101. In some embodiments, the interior surfaces 170 are oriented in a nonparallel and angled orientation relative to a major axis of the backing plate 1014.

The backing plate 1014 is directly coupled to the one or more electrode insulators 109 on an interior surface thereof and to the track 1003 via the support members 1025 and wheels 1005 on an exterior surface thereof. The backing plate 1014 is further coupled to extendable bellows 1015 disposed at one or more peripheral ends of the backing plate 1014. The backing plate 1014 is formed on any suitable process compatible material. In one embodiment, the backing plate 1014 is formed of an insulating material such as TFE, PEEK, ceramic, or the like. In other embodiments, the backing plate 1014 is formed of a metallic material and is electrically isolated from the process volume 101, the track 1003, and the bellows 1015.

In one embodiment, the bellows 1015 surround and couple the backing plate 1014 to the ceiling 1006. The bellows 1015 function to maintain a vacuum environment within the process volume 101 by extending or contracting as the moving electrode assembly 1007 is moved along the track 1003. The combination of the backing plate 1014 and the bellows 1015 functions as a dynamic ceiling for the chamber body 102 to isolate the process volume 101 from an exterior environment. It is also contemplated that other suitable types of vacuum feed-through devices may be utilized with the moving electrode assembly 1007.

The substrate support assembly 1010 is disposed in the process volume 101 and supports the substrate 111 on the substrate support surface 1010a thereon. The substrate support surface 1010a is oriented substantially parallel to the ceiling 106 and the major axis X. The substrate support assembly 1010 may be substantially similar to the substrate support assemblies discussed with reference to EBRPE chambers 100, 200, 300, 400, 600, and 800. For example, the substrate support assembly 1010 may be movable by a lift mechanism along the major axis Y. Additionally or alternatively, the substrate support assembly 1010 may be movable by servo along the major axis X. In another embodiment, the substrate support assembly 1010 is stationary.

In one embodiment, the substrate support assembly 1010 includes an insulating puck 1042 which forms the substrate support surface 1010a, an electrode 1044 disposed inside the insulating puck 1042, a base layer 1046, and a chucking voltage supply 1048 electrically coupled to the electrode 1044. In one embodiment, the base layer 1046 has internal passages 1049 for circulating a thermal transfer medium (e.g., a liquid) from a circulation supply 1045. In one embodiment, an RF bias power generator 1062 is coupled through an impedance match 1064 to the electrode 1044 of the substrate support assembly 1010. In a further embodiment, a waveform tailoring processor 1047 may be connected between the output of the impedance match 1064 and the electrode 1044. The controller 126 controls the waveform tailoring processor 1047.

During etching, the moving electrode assembly 1007 is moved along the one or more tracks 1003 in a either first or second axial direction X₁ or X₂, parallel to the major axis X. By moving the top electrodes 108 relative to the substrate 111, the moving electrode assembly 1007 performs a similar function to the movable substrate support assemblies described above, enabling averaging of non-uniform etching partially caused by the angled and nonparallel orientation of the top electrodes 108. Thus, the moving electrode assembly 1007 may be utilized as an alternative to the movable substrate support assemblies described with reference to chambers 100, 200, 300, 400, 600, and 800. However, it is also contemplated that the moving electrode assembly 1007 may be used in combination with a movable substrate support assemblies described above.

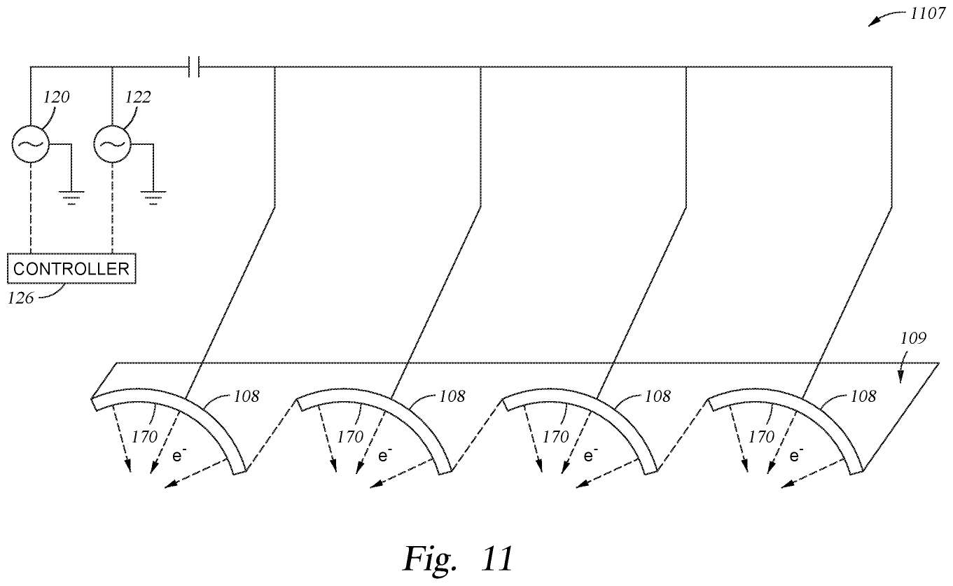

FIG. 11 depicts an embodiment of an electrode assembly 1107. The electrode assembly 1107 may be utilized in combination with any of the chambers and substrate supports described above. Similar to other embodiments described herein, the electrode assembly 1107 includes the top electrode 108 coupled to the electrode insulator 109. In one embodiment, two or more top electrodes 108 are coupled to a single electrode insulator 109. In another embodiment, each electrode 108 is coupled to a separate and distinct electrode insulator 109.

The top electrode 108 is formed from a process-compatible material having a high secondary electron emission coefficient. As depicted in FIG. 11, the top electrode 108 is shaped like an arced plate such that the interior surface 170 of the top electrode 108 is concave. The electrode insulator 109, formed of any suitable insulating material, has a corresponding rounded contact surface that supports the top electrode 108 adjacent the process volume 101. The top electrode 108 and the electrode insulator 109 are oriented such that an electron beam emitted from the top electrode 108 has an angled trajectory path relative to a substrate disposed in the chamber.

The concave shape of the interior surface 170 enables the emission of secondary electrons having multiple trajectory angles from a single top electrode 108. In one embodiment, the concave interior surface 170 may be shaped such that secondary electrons emitted from the top electrode 108 may be converged on a single point on the substrate. The convergence of secondary electrons emitted from a single top electrode 108 enables the formation of smaller features on the substrate while utilizing higher throughput, thus increasing etching efficiency. Furthermore, the concave shape of the interior surface 170 reduces the effects of any diverging or deviating secondary electrons emitting during etching, thus increasing the quality of the features formed during electron beam etching.

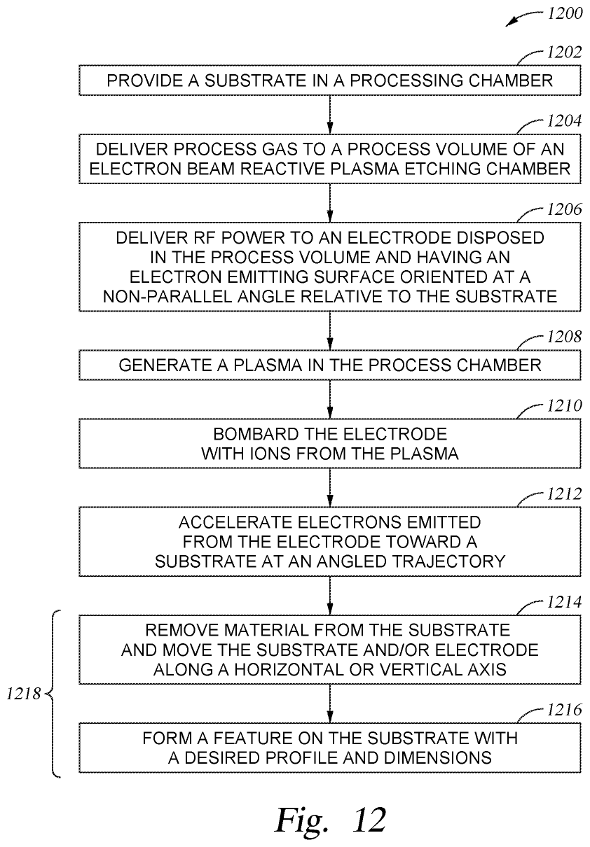

FIG. 12 is a flow chart depicting a process 1200 for performing an electron beam etching process utilizing any one of the embodiments described herein. In one specific example described herein, the process 1200 may utilize the chamber 100 depicted in FIG. 1. The process 1200 starts at operation 1202 by providing a substrate, such as the substrate 111 in the process chamber 100.

At operation 1204, a process gas is delivered to a process volume of an EBPRE chamber, such as the process volume 101 of the chamber 100. Various process gases, such as halogen containing gases or oxygen containing gases, are delivered to the process volume 101 through the gas injectors 130, 134 from the gas supplies 138. In one embodiment, an inert gas is also delivered to the process volume 101. In this embodiment, the inert gas is delivered through the upper gas injectors 130. Although not depicted with regard to FIG. 1, in another embodiment, the inert gas is delivered through the top electrode 108. By injecting an inert gas into the process volume, it is possible to reduce the probability of reactive species back diffusion and better maintain an integrity of a plasma formed in the process volume.

In one example, the process gases delivered into process volume 101 are an etching gas mixture. The etching gas mixture may include a reacting gas and an optional inert gas. The reacting gas may include a halogen gas, such as Cl₂, CF₄, CH₂F₂, NF₃, HCl, HBr, SF₆, and the like. Suitable examples of the inert gas include Ar and He. The etching gas mixture supplied to the process volume in chamber 100 may assist absorption of the etchants absorbed into the substrate surface and distributed across the substrate surface as well as in the chamber.

At operation 1206, an RF power is delivered to an electrode disposed in the process volume and having an electron emitting surface oriented at a nonparallel angle relative to the substrate, such as the top electrode 108. In one embodiment, the delivered RF power has a low frequency, such as a frequency less than 60 MHz. For example, an RF power having a frequency of about 2 MHz or about 13.56 MHz is delivered to the top electrode 108. The RF power is applied to the top electrode 108 so as to energize the process gases in the process volume 101 and form a plasma at operation 1208. Utilizing a low RF frequency power enables generation of a plasma with a high sheath voltage. As a result, ions can be accelerated toward the top electrode 108, bombarding the interior surface 170 of the top electrode 108 to cause secondary electron emission. In one embodiment, the RF power is applied to the top electrode 108 in a pulsed manner. In one embodiment, the RF power is applied to the top electrode 108 in a continuous manner. In other embodiments, RF power is applied to an inductive coil assembly disposed adjacent to the top electrode 108 to form an inductively coupled plasma at operation 1208.

In one embodiment, the platform 110 is maintained at ground potential. In another embodiment, low frequency RF power is applied to the platform 110. In this embodiment, the RF power applied to the platform 110 is concurrent with the RF power applied to the top electrode 108. Alternatively, the RF power applied to the platform 110 is delivered when substantially no RF power is supplied to the top electrode 108. In embodiments where RF power is applied to the platform 110, the RF power is controlled to reduce adverse influence on the plasma sheath potential to prevent impedance of electron beams from reaching the substrate 111.

It is also contemplated that the RF power applied to the top electrode 108 can be synchronized with the RF power applied to the platform 110 by pulsing such that the duty cycles of the top electrode 108 RF power and the platform 110 RF power do not overlap. As a result, electrical biasing within the process volume 101 is not substantially limited and impedance of the electron beams due to the plasma sheath bias potential is substantially mitigated.

At operation 1210, the top electrode 108 is bombarded with ions from the formed plasma. In this embodiment, the plasma has a predominantly positive charge and the top electrode 108 has a predominantly negative charge. Ions from the plasma are influenced by an electric field generated in the process volume 101 and the ions accelerated toward the top electrode 108, thus heating the top electrode 108. Because the electrode is formed from a material having a high secondary electron emission coefficient, the ion bombardment of the top electrode 108 causes secondary electrons to be emitted from the top electrode 108.

At operation 1212, after the plasma is generated and the top electrode 108 is bombarded to generate the secondary electrons, the secondary electrons are accelerated toward the substrate 111. Due to the substantially negative charge of the top electrode 108, the negatively charged electrons are repelled by the top electrode 108 towards the substrate 111. In one embodiment, a negative DC may be applied to the process chamber 100 to further increase the energy or momentum of the secondary electrons, thus increasing etching rate. It is also contemplated that the plasma sheath voltage potential further functions to accelerate the electrons toward the substrate 111. As the electrons are accelerated by the plasma sheath voltage, the electrons acquire energy of between about 100 electron volts (eV) and about 10,000 eV upon entry into the plasma. The electrons emitted from the top electrode 108 generate a large area secondary electron beam.

The angled orientation of the electron emitting surface of the top electrode 108 results in an angled trajectory of the electron beam through the process volume 101. In one embodiment, the electron beam has a predetermined angle of emission substantially perpendicular to the interior surface 170 of the top electrode 108. As a result, the electron beam may etch the substrate 111 with an incident or tilt angle.

At operation 1214, material is removed from the substrate 111. The electrons in the electron beam are believed to react with the process gases to further generate additional radicals and ions which adsorb to surfaces of the substrate 111. The adsorbed materials form a chemically reactive polymer layer on the surface of the substrate. The electron beam also facilitates polymer layer reaction with the substrate 111 to generate gas phase volatile products, thus etching the surface of the substrate 111.

During operation 1214, the substrate 111 and/or the top electrode 108 are actuated along a major axis of the substrate 111 while material is being removed from the substrate 111. By moving the substrate 111 and/or the top electrode 108 relative to one another, secondary electron flux partially caused by the tilted orientation of interior surface 170 may be substantially diminished, as exposure of each point on the substrate 111 to secondary electrons emitted from the top or bottom end of the electrode 108 may be controlled. In one embodiment, the substrate 111 is actuated along an axis perpendicular to an upper surface of the substrate at varying speeds in order to modulate the depth of features formed on the substrate 111.

At operation 1216, material continues to be removed from the substrate 111 as the substrate 111 and/or top electrode 108 are actuated, and while the electron beam continues to generate and accelerate towards the substrate surface, until the desired features with desired profiles and dimensions are formed.

It is noted that operations 1214 and 1216 can be repeatedly performed, as indicated by the loop 1218, until a desired feature with a desired profile is obtained at operation 1216.

By utilizing electron beams generated in accordance with the embodiments described above, reactive species which are not readily obtained with conventional etching processes may be generated. For example, reactive species with high ionization and/or activation/dissociation energies may be obtained with the electron beam etching methods and apparatus described herein. It is also believed that the electron beam etching methods described herein provide for etching rates equivalent to or greater than conventional etching processes, but with improved material selectivity. Furthermore, the electron beam etching methods described herein enable the precise and efficient utilization of lateral electron beams directed to the substrate at desired incident angles, thus forming features in the substrate having sloped sidewalls as needed.

While the foregoing is directed to embodiments of the present disclosure, other and further embodiments of the disclosure may be devised without departing from the basic scope thereof, and the scope thereof is determined by the claims that follow.

1. A chamber for electron beam etching, comprising:
a chamber body having sidewalls and a chamber bottom, the sidewalls and chamber bottom at least partially defining a process volume;
one or more gas injectors disposed through the sidewalls of the chamber body;
a substrate support assembly, the substrate support assembly comprising:
an insulating puck; and
a first electrode disposed within the insulating puck;
a ceiling coupled to the chamber body and further defining the process volume;
one or more tracks coupled to the ceiling;
a movable electrode assembly coupled to the one or more tracks, the movable electrode assembly comprising:
a second electrode having a surface, the surface disposed at a nonparallel angle relative to a major axis of the substrate support assembly;
an insulating member coupled to the second electrode; and
a backing plate coupled to the insulating member; and
a bellows assembly disposed at one or more peripheral ends of the backing plate.

2. The chamber of claim 1, wherein the second electrode is formed from a material having a high secondary electron emission coefficient.

3. The chamber of claim 2, wherein the second electrode is formed from one or more of silicon containing materials, carbon containing materials, silicon-carbon containing materials, or silicon-oxide containing materials.

4. The chamber of claim 2, wherein the second electrode is formed from a metal oxide material.

5. The chamber of claim 4, wherein the metal oxide material is selected from the group consisting of aluminum oxide, yttrium oxide, and zirconium oxide.

6. The chamber of claim 2, wherein the second electrode has a substantially plate-like shape.

7. The chamber of claim 2, wherein the second electrode has a substantially wedge-like shape.

8. The chamber of claim 1, wherein the surface of the second electrode is disposed at a nonparallel angle of between 20 degrees and 70 degrees relative to the major axis of the substrate support assembly.

9. The chamber of claim 1, wherein the surface of the second electrode is disposed at a nonparallel angle of between 35 degrees and 55 degrees relative to the major axis of the substrate support assembly.

10. The chamber of claim 1, further comprising an RF power generator electrically coupled to the second electrode.

11. The chamber of claim 1, further comprising a DC power generator electrically coupled to the second electrode.

12. The chamber of claim 11, further comprising an inductive coil assembly disposed adjacent to the second electrode and coupled to an RF power generator.

13. The chamber of claim 1, further comprising one or more support members coupled to the backing plate, each support member coupled to one or more wheels disposed on the one or more tracks.

14. The chamber of claim 1, wherein the one or more tracks are maglev tracks.

15. A movable electrode assembly for electron beam etching, comprising:
a backing plate;
an insulating member coupled to the backing plate;
an electrode coupled to the insulating member, the electrode having a surface disposed at a nonparallel angle relative to the backing plate; and
one or more support members coupled to the backing plate, each support member having one or more wheels coupled to a track.

16. The movable electrode assembly of claim 15, wherein the electrode is formed from a material having a high secondary electron emission coefficient.

17. The movable electrode assembly of claim 15, wherein the electrode is formed from one or more of silicon containing materials, carbon containing materials, silicon-carbon containing materials, or silicon-oxide containing materials.

18. The movable electrode assembly of claim 15, wherein the electrode is formed from a metal oxide material.

19. The movable electrode assembly of claim 15, further comprising a bellows assembly disposed at one or more peripheral ends of the backing plate.

20. (canceled)
